(19) United States
(12) Patent Application Publication
(10) Pub. No.: US 2023/0110366 A1
(43) Pub. Date: Apr. 13, 2023

(54) COMPOSITE NANOPARTICLE COMPOSITIONS AND ASSEMBLIES

(71) Applicant: Wake Forest University, Winston-Salem, NC (US)

(72) Inventors: David L. CARROLL, Winston-Salem, NC (US); Chaochao DUN, Winston-Salem, NC (US); Corey HEWITT, Winston-Salem, NC (US); Robert SUMMERS, Clemmons, NC (US)

(21) Appl. No.: 17/856,854

(22) Filed: Jul. 1, 2022

Related U.S. Application Data
(63) Continuation-in-part of application No. 16/486,341, filed on Aug. 15, 2019.
(60) Provisional application No. 62/459,978, filed on Feb. 16, 2017.
(60) Provisional application No. 63/217,670, filed on Jul. 1, 2021.

(51) Int. Cl. H10N 10/853; C09K 11/88; H10N 10/857

(52) U.S. Cl. CPC H01L 35/18; C09K 11/881; H01L 35/26; C01P 2004/24; C10N 2020/06

(57) ABSTRACT

Composite nanoparticle compositions and associated nanoparticle assemblies exhibit enhancements to one or more thermoelectric properties including increases in electrical conductivity and/or Seebeck coefficient and/or decreases in thermal conductivity. A composite nanoparticle composition comprises a semiconductor nanoparticle including a front face and a back face and sidewalls extending between the front and back faces. Metallic nanoparticles are bonded to at least one of the sidewalls establishing a metal-semiconductor junction.

### RELATED APPLICATION DATA

This application is a continuation in part of U.S. Ser. No. 16/486,341 filed Aug. 15, 2019, which is a national stage entry of PCT/US18/00041 filed Feb. 16, 2018, and claims priority to U.S. provisional application 62/459,978 filed Feb. 16, 2017. This application also claims priority to U.S. provisional application 63/217,670 filed Jul. 1, 2021. The above listed applications are incorporated by reference in their entirety.

### STATEMENT OF GOVERNMENT RIGHTS

This invention was made with government support under Grant No. FA9550-16-1-0328 awarded by the U.S. Air Force Office of Scientific Research and Grant No. 1123-SC-0I-R0 NASA #NNX16CJ30P awarded by NASA/Streamline. The government has certain rights in the invention.

### FIELD OF THE INVENTION

The present invention relates to composite nanoparticles and associated assemblies and, in particular, to composite nanoparticles and assemblies exhibiting enhanced thermoelectric properties.

### BACKGROUND

Solid-state energy conversion utilizing thermoelectric (TE) materials has attracted increasing interest due to their unparalleled properties to convert waste heat to electric energy. The efficiency of TE materials is expressed by a dimensionless figure of merit ZT, which is governed by electrical conductivity (a), Seebeck coefficient (S), and thermal conductivity (K) that mainly includes the lattice thermal conductivity κ_{L} and carrier thermal conductivity κ_{c}(κ_{L}>>κ_{c}). An ideal efficient TE material necessarily to possesses high σ and a low κ. Unfortunately, for most TE systems, these three parameters are interdependent, thus maximizing one normally counteracts or reduces other two. This has ultimately prevented the widespread application of TE materials as noise-free power generators or scalable solid-state Peltier coolers.

### SUMMARY

Composite nanoparticle compositions and associated nanoparticle assemblies are described herein which, in some embodiments, exhibit enhancements to one or more thermoelectric properties including increases in electrical conductivity and/or Seebeck coefficient and/or decreases in thermal conductivity. In one aspect, a composite nanoparticle composition comprises a semiconductor nanoparticle including a front face and a back face and sidewalls extending between the front and back faces. Metallic nanoparticles are bonded to at least one of the sidewalls establishing a metal-semiconductor junction. In some embodiments, the metallic nanoparticles are bonded to a plurality of the semiconductor nanoparticle sidewalls establishing multiple metal-semiconductor junctions.

In another aspect, composite nanoparticle assemblies are described herein. Briefly, a composite nanoparticle assembly comprises semiconductor nanoparticles comprising front and back faces and sidewalls extending between the front and back faces, wherein spacing between the semiconductor nanoparticles is bridged by metallic nanoparticles bonded to the sidewalls of the semiconductor nanoparticles. As described further herein, the bridging metallic nanoparticles establish metal-semiconductor junctions with sidewalls of the semiconductor nanoparticles.

In a further aspect, methods of enhancing chalcogenide thermoelectric performance are provided. In some embodiments, a method of enhancing chalcogenide thermoelectric performance comprises providing chalcogenide nanoparticles comprising front and back faces and sidewalls extending between the front and back faces. At least one of electrical conductivity and Seebeck coefficient of the chalcogenide nanoparticles is increased via nucleation of metallic nanoparticles on the sidewalls, wherein the metallic nanoparticles bridge spacing between the chalcogenide nanoparticles. Moreover, thermal conductivity of the chalcogenide nanoparticles can be decreased by the metal nanoparticles bridging spacing between adjacent nanoparticles.

These and other embodiments are described in greater detail in the following detailed description.

### BRIEF DESCRIPTION OF THE DRAWINGS

FIG. 1A illustrates a top plan view of a platelet semiconductor nanoparticle according to some embodiments.

FIG. 1B illustrate metallic nanoparticles bonded to sidewalls of the platelet semiconductor nanoparticle according to some embodiments.

FIG. 2A illustrate band structure of Sb₂Te₃ nanoparticle and Ag metal according to some embodiments.

FIG. 2B illustrate band structure of an Ag nanoparticle-Sb₂Te₃ nanoparticle interface according to some embodiments.

FIG. 3 illustrates a composite nanoparticle assembly according to some embodiments.

FIG. 4 illustrates transmission electron microscopy (TEM) images of composite nanoparticles according to some embodiments.

FIGS. 5A and 5B illustrate X-ray diffraction measurements of Sb₂Te₃ nanoplates and Sb₂Te₃ nanoplates having silver nanoparticles bound to sidewalls according to some embodiments.

FIG. 6 illustrates a high resolution TEM image of a composite nanoparticle according to some embodiments.

FIGS. 7A-7F illustrate XPS of Sb₂Te₃ and Ag-decorated Sb₂Te₃ conducted to study the chemical environment of each element.

FIGS. 8A and 8B illustrate results of TGA and DSC analyses of Sb₂Te₃ nanoplates and Ag-decorated Sb₂Te₃ nanoplates according to some embodiments.

FIG. 9A illustrates temperature dependent electrical properties of Ag-decorated Bi₂Te₃ pellets with different Ag concentrations.

FIG. 9B illustrates temperature dependent thermal transport properties of Ag-decorated Bi₂Te₃ pellets with different Ag concentrations.

FIG. 10 illustrates temperature dependent electrical and thermal transport properties of Cu-decorated Bi₂Te₃ pellets with different Cu concentrations.

FIGS. 11A and 11B summarize the room temperature (RT) performance for Cu- and Ag-decorated Bi₂Te₃, respectively.

FIG. 12 provides scanning electron microscopy images of pellet based Bi₂Te₃ nanoplates after Ag decoration at different magnifications according to some embodiments.

FIGS. 13A-13D are graphs showing temperature dependent electrical and thermal transport properties of Ag decorated Bi₂Te₃ nanoplate samples.

FIGS. 14A-14D are graphs showing temperature dependent electrical and thermal transport properties of Cu-decorated Bi₂Te₃ nanoplate samples.

FIGS. 15A-15H are graphs illustrating relationships between various parameters and decoration metal concentrations for Bi₂Te₃ nanoplate samples.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

In one aspect, a composite nanoparticle composition comprises a semiconductor nanoparticle including a front face and a back face and sidewalls extending between the front and back faces. Metallic nanoparticles are bonded to at least one of the sidewalls establishing a metal-semiconductor junction. In some embodiments, the metallic nanoparticles are bonded to a plurality of the semiconductor nanoparticle sidewalls establishing multiple metal-semiconductor junctions. The semiconductor nanoparticle can comprise any semiconductor not inconsistent with the thermoelectric principles and electronic structures described herein. Suitable semiconductor nanoparticles can include various chalcogenides, such as metal sulfides, metal selenides and/or metal tellurides. Moreover, semiconductor nanoparticles can be p-type or n-type. For example, semiconductor nanoparticles can comprise molybdenum sulfide (MoS₂), antimony telluride (Sb₂Te₃) or bismuth telluride (Bi₂Te₃). Additionally, semiconductor nanoparticles of the composite composition can exhibit any particle morphology presenting sidewalls for bonding and/or nucleation of the metallic nanoparticles. In some embodiments, semiconductor nanoparticles have two-dimensional (2D) morphology. A semiconductor nanoparticle, for example, can be a platelet wherein the metal nanoparticles are bonded to one or more sidewalls of the platelet. Semiconductor nanoparticles, in some embodiments, exhibit a pyramidal or bi-pyramidal structure.

Metallic nanoparticles bonded to one or more sidewalls of a semiconductor nanoparticle can comprise any metal not inconsistent with the thermoelectric principles and electronic structures described herein. Suitable metals include various transition metals, such as metals selected from Groups IVA-VIIIA and Group 1B of the Periodic Table. In some embodiments, the metallic nanoparticles are formed of noble metal(s). The metal nanoparticles can nucleate and self-assemble on sidewall surfaces of the semiconductor nanoparticles. In being bonded to the semiconductor nanoparticle sidewall, an interfacial transition region can be established between the metal nanoparticle and semiconductor. In some embodiments, the interfacial transition region comprises metal atoms chemically bonded to atoms of the semiconductor nanoparticle.

In one example, silver nanoparticles are bonded to sidewalls of a Sb₂Te₃ nanoparticle, wherein an interfacial transition region comprises Sb₂Te₃—Ag₂Te—Ag. Metal nanoparticles bonded to semiconductor sidewalls can have any size not inconsistent with the objectives of the present invention. In some embodiments, metal nanoparticle size is governed by spacing between the semiconductor nanoparticles in a composite assembly. As described further herein, the metal nanoparticles can bridge spacing between adjacent semiconductor nanoparticles, binding to sidewalls of the semiconductor nanoparticles. In such embodiments, composite nanoparticle assemblies can be formed.

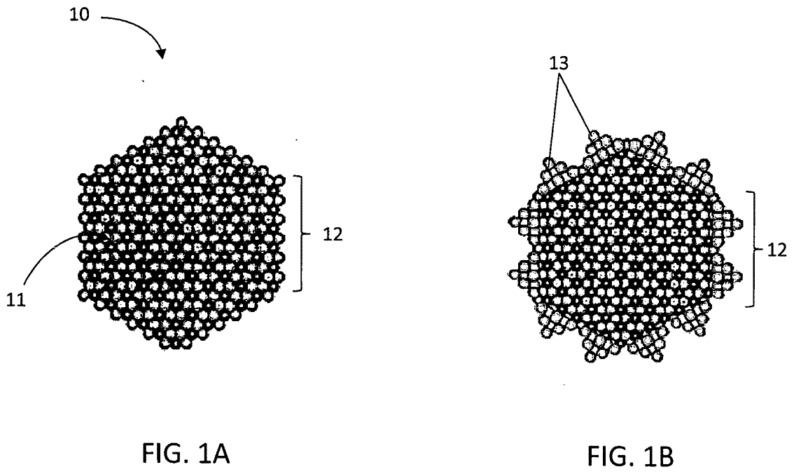

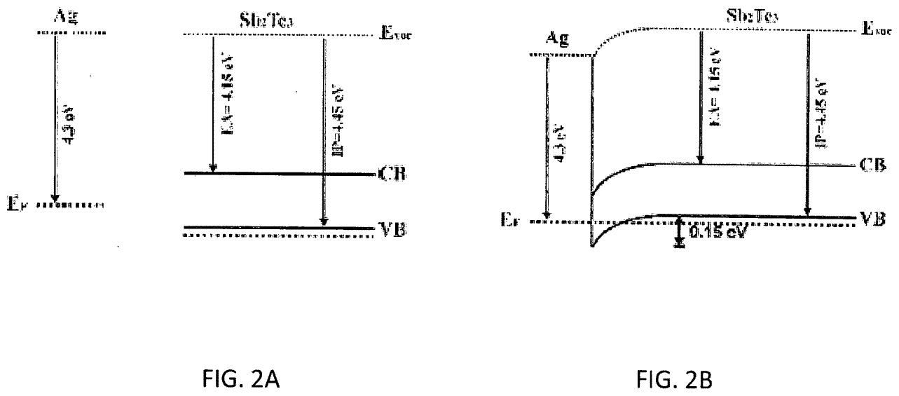

FIG. 1A illustrates a top plan view of a Bi₂Te₃ nanoparticle having a hexagonal nanoplatelet morphology according to some embodiments described herein. The Bi₂Te₃ nanoparticle 10 comprises a front face 11 and an opposing back face (not shown). The hexagonal nanoplatelet may have a thickness of about 20 nm to about 50 nm. Sidewalls 12 extend between the front face 12 and back face. The sidewalls may have a length of from 350 nm to at least 600 nm. The distance between opposing sidewalls may be, for example, from about 500 nm to about 1000 nm. FIG. 1B illustrates metallic nanoparticle 13 nucleation and growth on sidewalls 12 of the Bi₂Te₃ nanoparticle 10.

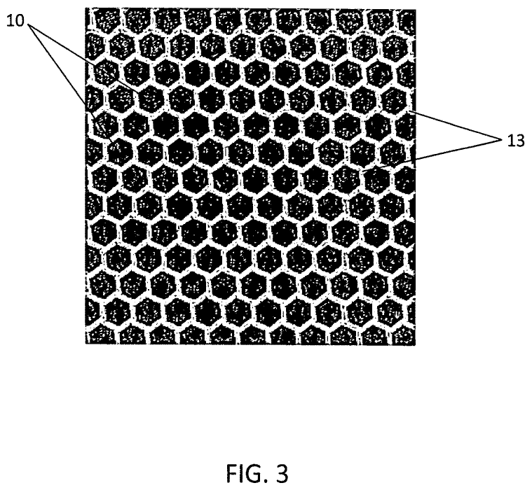

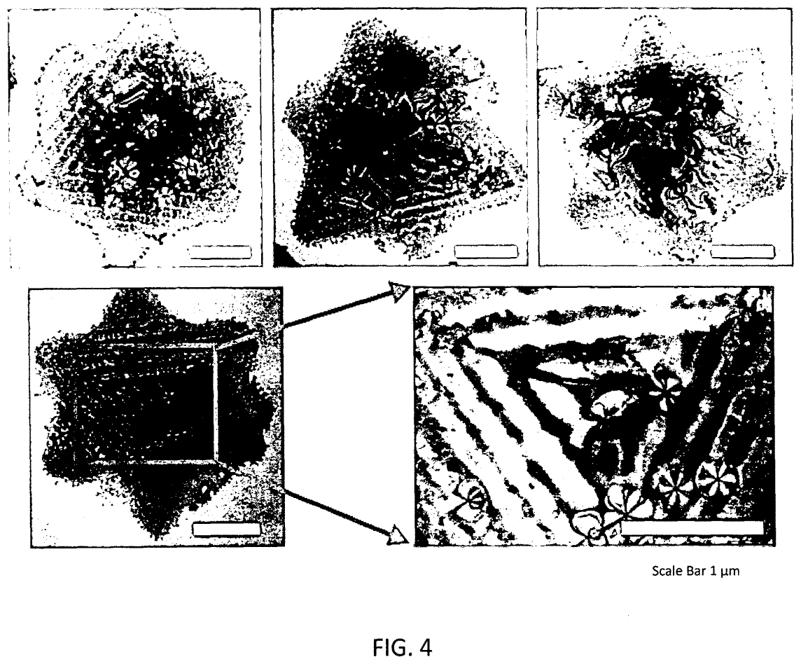

Bonding and growth of metallic nanoparticles on sidewalls of the semiconductor establishes a metal-semiconductor junction. In some embodiments, a Schottky barrier is formed at the metal semiconductor junction. FIG. 2A illustrates the band diagram of a Sb₂Te₃ nanoparticle prior to nucleation and growth of silver nanoparticles along one or more sidewalls. The work function of silver is also illustrated in FIG. 2A. Before contact, the initial Fermi level of Ag is located above the intrinsic Sb₂Te₃. After nucleation and growth, the presence of Ag nanoparticles pins the effective Fermi level of the present nanocomposites around the work function of silver due to the large carrier density in the metallic layer. As can be seen in FIG. 2B, the blend band gap between the host Sb₂Te₃ semiconductor and metallic Ag nanoparticles forms a Schottky barrier, which is believed to be much better than Ohmic contact. Moreover, the potential barrier height (˜150 meV) is around the theoretical optimized height of 100 meV. Therefore, interfaces in Ag—Sb₂Te₃ nanoplates induce energy-dependent carrier scattering by introducing a Schottky barrier to filter carriers with low energy, i.e. the carrier filtering technique prevents the transport of the lower-energy carriers, which results in an increase in the moment of the differential conductivity about the Fermi level.

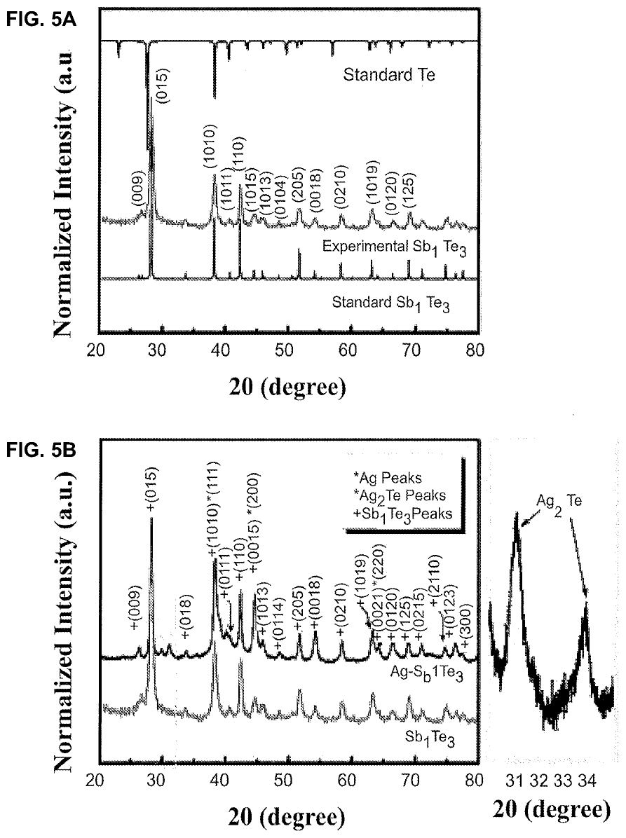

The metallic nanoparticles bridge spacing between adjacent semiconductor nanoparticles to provide composite nanoparticle assemblies. A metal nanoparticle, for example extends from a sidewall of a first semiconductor nanoparticle to bond to a sidewall of a second adjacent semiconductor nanoparticle. When occurring over multiple sidewalls, nanocomposite assemblies are formed as illustrated in FIG. 3. Spacing between the platelet Sb₂Te₃ nanoparticles 10 is filled with metallic nanoparticles 13 bound to sidewalls of the Sb₂Te₃ nanoparticles. Schottky barriers can be established at metal-semiconductor interfaces along the sidewalls permitting filtering of low energy carriers as described herein. Filtering of the low energy carriers can enhance electrical conductivity of the composite nanoparticle assembly. In some embodiments, a nanocomposite assembly has an electrical conductivity of at least 1×10⁴ S/m or at least 1×10⁵ S/m. Additionally, the metal nanoparticles can enhance phonon scattering, thereby lowing thermal conductivity of the nanocomposite assembly. Seebeck coefficient of the semiconductor nanoparticles can also be improved by the presence of the metal nanoparticles. In some embodiments, a nanocomposite assembly has a room temperature Seebeck coefficient of at least 140 μV/K. The foregoing enhancements also increase the power factor of composite nanoparticle assemblies described herein. In some embodiments, a nanoparticle assembly has a power factor greater than 600 μW/mK² or a power factor greater than 1000 μW/mK².

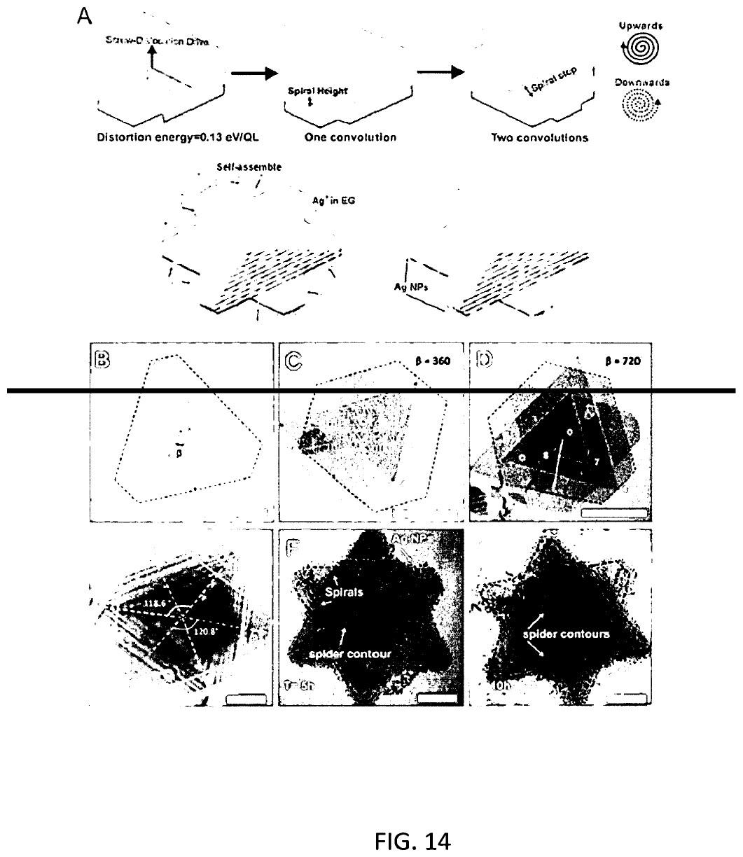

Composite nanoparticle assemblies can be formed into thin flexible films for various thermoelectric applications. Composite nanoparticle assemblies, in some embodiments, are stacked to provide thin film architectures. Cross-sectional structure of the stacked composite assemblies can include porosity or open spaces between composite nanoparticle assemblies. Such porosity and/or open spaces are illustrated in FIG. 12. FIG. 12 provides scanning electron microscopy (SEM) images of pellet based Bi₂Te₃ nanoplates after Ag decoration at different magnifications according to some embodiments.

In a further aspect, methods of enhancing chalcogenide thermoelectric performance are provided. In some embodiments, a method of enhancing chalcogenide thermoelectric performance comprises providing chalcogenide nanoparticles comprising front and back faces and sidewalls extending between the front and back faces. At least one of electrical conductivity and Seebeck coefficient of the chalcogenide nanoparticles is increased via nucleation of metallic nanoparticles on the sidewalls, wherein the metallic nanoparticles bridge spacing between the chalcogenide nanoparticles. Moreover, thermal conductivity of the chalcogenide nanoparticles can be decreased the metal nanoparticles bridging spacing between adjacent nanoparticles.

These and other embodiments are further illustrated in the following non-limiting examples.

### Example 1—Composite Nanoparticle Assembly

V-VI Sb₂Te₃ was selected because of its state-of-the-art performance that exhibits the highest ZT near 50° C. Silver was chosen as the metallic nanoparticle phase due to its low work function (4.26-4.9 eV) needed for efficient carrier injection into the Sb₂Te₃ conduction band. In detail, using the ultrathin/active Sb₂Te₃ edge as the nucleation sites, Ag can be reduced from AgNO₃ in ethyl alcohol (EG) at room temperature. As a result, Ag nanoparticles with diameters around 40 nm were found to grow uniformly at the edge of the Sb₂Te₃ nanoplates.

Actually, a slight layer of second phase (n-type Ag₂Te) was also introduced in this process. These interfaces among Sb₂Te₃—Ag₂Te—Ag act as a low-energy carrier and phonon scattering center, which facilitates the enhancement of the Seebeck coefficient (from 84 to 103 μV/K) and the suppression of thermal conductivity. Meanwhile, the electrical conductivity was also improved from 4.4×10³ to 3.5×10⁴ S/m due to the increased carrier concentration with a slight decrease of carrier mobility. This simultaneous enhancement of electrical conductivity and Seebeck coefficients demonstrates that these self-assembled Ag nanoparticles are able to inject charge carriers and facilitate charge transport between Sb₂Te₃ nanoplates; at the same time, the generated the energy barrier among Ag nanoparticles, the introduced Ag₂Te second phase and Sb₂Te₃ nanoplatelets also assist in blocking charge carriers with lower energy, facilitate the decoupling of the Seebeck coefficient and electrical conductivity.

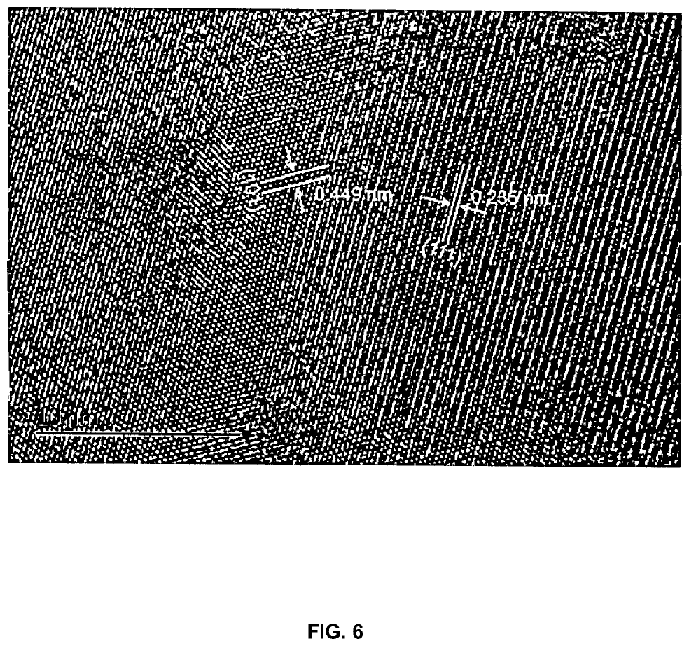

In a typical synthesis, 70 ml ethylene glycol (EG) solution containing mixed antimony trichloride (SbCl₃, 6 mmol), tellurium dioxide (TeO₂, 9 mmol), sodium hydroxide (NaOH, 1.5 g), and polyvinylpyrrolidone (PVP, Ms˜40000 g/mol, 0.8 g) is heated to 120° C. 10 ml hydrazine hydrate (N₂H₄) is injected (with injection rate 2.5 ml/min), and the solution is maintained at 130° C. for 3 hours, after which, the mixture is heated at 155° C. under reflux for another 15 hours. The precipitate is collected by centrifugation, and washed using ethanol at least three times. Finally, a simple and efficacious vacuum filtration process is adopted to fabricate the Sb₂Te₃-based thin film using water as solution. In detail, the Sb₂Te₃-based nanocomposites are dispersed in water via homogenization and sonication, subsequently, the resulting aqueous suspension is vacuum-filtered through a poly(vinylidene difluoride) (PVDF) filter (0.1 μm pore size) to form a silver gray film (shiny metallic appearance) on the filter surface. The fabricated thin film may be transferred to different substrates (like Silicon or PET) for different applications. For the fabrication of Ag-decorated Sb₂Te₃ nanocomposites, 1 mmol as-fabricated Sb₂Te₃ is dispersed in 70 mL EG, and a proper amount of AgNO₃ is added with gentle stirring over night at room temperature. The precipitate is collected by centrifugation, and washed with ethanol at least three times. Finally, vacuum filtration is used to fabricate the flexible thin film based on Ag-decorated Sb₂Te₃. Ag nanoparticles with high uniformity are observed to embed regularly around the edges of the Sb₂Te₃ nanoplates, as evidenced by TEM images of FIG. 4. The Sb₂Te₃ nanoplates shown in FIG. 4 are bipyramidal nanoplates that are greater than 1 μm across between opposing sides.

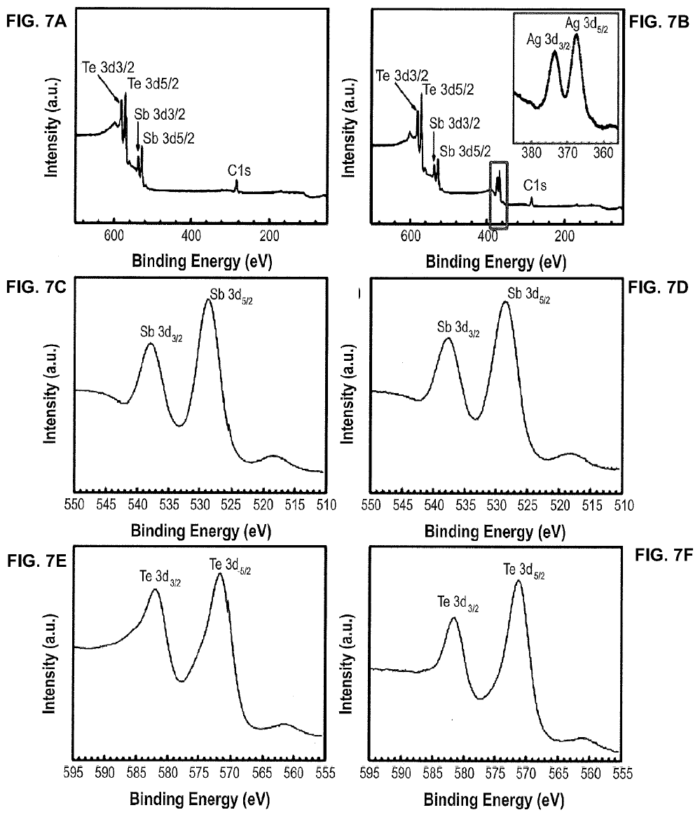

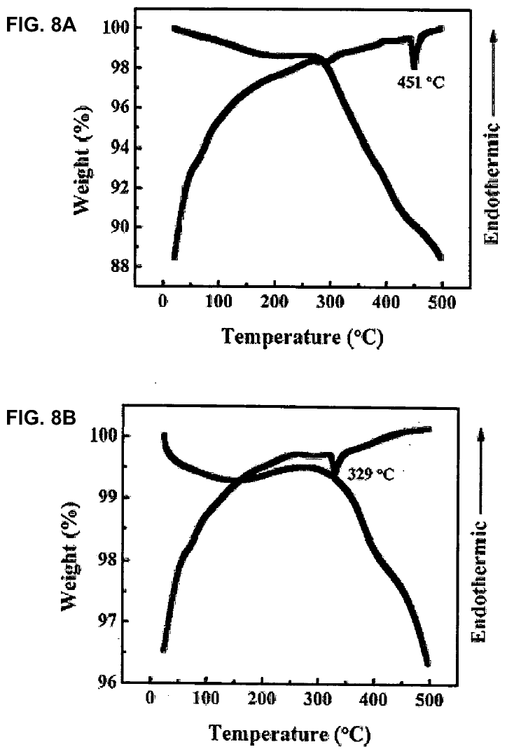

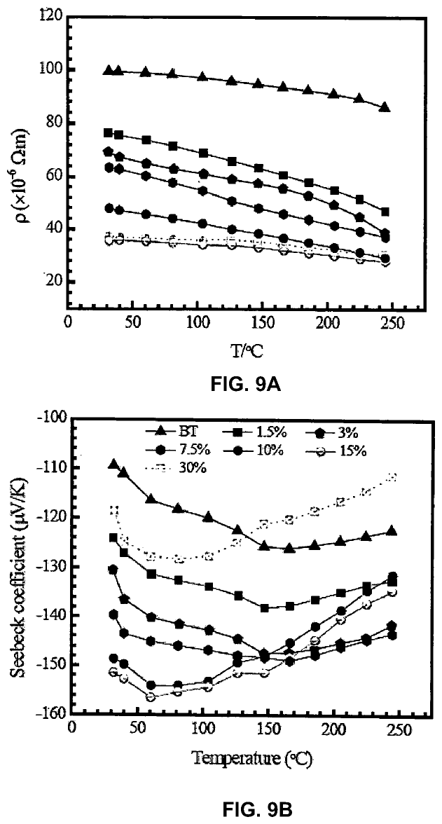

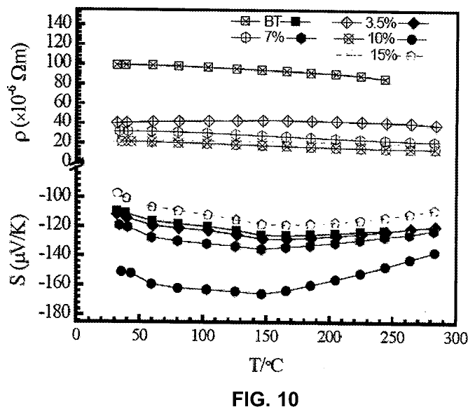

The active Sb₂Te₃ edges with exposed Te dangling bonds are believed to act as heterogeneous nucleation sites, first reacting with Ag⁺ and then facilitating the growth of Ag nanoparticles with the help of a reducing agent (EG). No dissociate Ag nanoparticles were found in the solution (dynamically unstable) or on the surface of the Sb₂Te₃ nanoplates, suggesting that laterally selective growth is more preferable (calculated as −0.113 eV/Å² compared with −0.037 eV/Å² for growth on the face). The strain in the crystal lattice is beneficial to the decrease of the lattice thermal conductivity contribution by strain field scattering. By using XRD measurement, a slight amount of Ag₂Te was also found beyond Ag (peaks 29.8° and 31° that correspond to the main peak of monoclinic phase Ag₂Te), which likely occurs in the beginning of nucleation as illustrated in FIG. 5A and FIG. 5B. That is in agreement with the slight layer (˜3 nm) of second phase (n-type Ag₂Te, P2/n, and PDF No. 34-0142) observed by HRTEM in FIG. 6, implying the uniformly generated Sb₂Te₃—Ag₂Te—Ag interfaces. Here, by using self-assembled nanoengineering, a uniform p-n junction was generated around each Sb₂Te₃ nanoplate, which might be one of the main reasons this unique heterojunction has extremely high electrical conductivity while maintaining a decent Seebeck coefficient. XPS of Sb₂Te₃ and Ag-decorated Sb₂Te₃ have been conducted to study the chemical environment of each element as provided in FIGS. 7A-7F. The 3d_{3/2} and 3d_{5/2} peaks of Ag are located at 373.40 and 367.8 eV, respectively. A slight shoulder peak appears in the Sb₂Te₃ sample due to the oxidation states of Te compared to the sharp peak of the Ag-decorated Sb₂Te₃ sample. This means the oxidative stability of the nanocomposites is strengthened after Ag-decoration. TGA and DSC analyses of Sb₂Te₃ nanoplates and Ag-decorated Sb₂Te₃ nanocomposites are given in FIGS. 8A and 8B.

Ag-decorated Sb₂Te₃ nanocomposites possess significantly higher electrical conductivities around 3.5×10⁴ S/m, which is eight times larger than that of the Sb₂Te₃ based thin film and even comparable to the bulk Sb₂Te₃ pellet. At the same time, the Seebeck coefficient also increases from 84 to 103 μV/K at 300 K (>20%) after nanoengineering. As a result, with the enhanced electrical conductivity and improved Seebeck coefficient, Ag-decorated Sb₂Te₃ nanocomposite based films give a power factor of 371 μW/mK², which is much higher than previous Bi₂Se₃-based thin films and other Sb₂Te₃-based films. The electrical conductivity and Seebeck of the present films exhibited high stability against the bending test, demonstrating no apparent change in performance upon repeated bending for up to 500 cycles under bending radius 2 mm. The boost in performance results from the simultaneously enhanced electrical conductivity and Seebeck coefficients. Here, the enhanced electrical conductivity is explained by an efficient injection of carriers from the metallic Ag to the conduction band of the Sb₂Te₃ semiconductor. To clarify the above mechanism, a room temperature hall measurement was performed, which reveals a remarkable increase in carrier concentration from 1.4×10¹⁹ cm⁻³ to 9.9×10¹⁹ cm⁻³ with a slight decrease of mobility from 25 to 22 cm²V⁻¹S⁻¹, as can be seen in Table 1. This is also in agreement with the estimated results from the increase of equivalent conductivity (in unit of the relaxation time t) for Ag-decorated Sb₂Te₃ nanocomposites compared with Ag-free Sb₂Te₃ based on first-principles calculations.

TABLE 1
Carrier concentrations and carrier motilities Sb₂Te₃ based
or Sb₂Te₃ related nanostructures based thin films at 300 K.

| | Carrier | | | Electrical | Power |
|---|---|---|---|---|---|
| | Concentration | Mobility | Seebeck | Conductivity | Factor |
| Materials | (×10¹⁹ cm⁻³) | (cm²V⁻¹S⁻¹) | (μV/K) | (S/m) | (μW/mK²) |
| Sb₂Te₃ | 1.67 | 28 | 116 | 7.3 × 10³ | 96 |
| Pt—Sb₂Te₃ | 2.46 | 11.4 | 152 | 4.4 × 10³ | 102 |
| Sb₂Te₃ | | | | | |
| Annealed 420 K | 1.5 | 14 | 124 | 3.9 × 10³ | 60 |
| Annealed 470 K | 1.7 | 26 | 114 | 7.0 × 10³ | 91 |
| AgₓTe_{y}—Sb₂Te₃ | 8.9 | 4.1 | 135 | 5.6 × 10³ | 102 |
| Ag₃₁Sb₁₉Te₅₀ | | | | | |
| AgₓTe_{y}—Sb₂Te₃ | 11 | 5.8 | 93 | 1.07 × 10⁴ | 93 |
| Ag₃₄Sb₁₈Te₄₈ | | | | | |
| Sb₂Te₃^{a)} | 1.4 | 25 | 84 | 5.6 × 10³ | 40 |
| Ag—Sb₂Te₃^{a)} | 9.9 | 22 | 103 | 3.5 × 10⁴ | 371 |

^{a)}The results in the present work without annealing.

A beneficial energy barrier is introduced between the metallic nanoparticles and semiconductor nanoplates to maintain a decent Seebeck coefficient. The band alignment between Sb₂Te₃ and Ag nanoparticles is shown in FIGS. 2A and 2B. The detailed electrical information 5 of Sb₂Te₃ and the work function of silver nanoparticles (˜4.3 eV) are taken from experiments.

The assumption of bulk is reasonable since the thickness of the bottom layer of Sb₂Te₃ is around 10 nm, which corresponds to 10 QL. The Fermi level (E_{F}) is positioned near the top of valence band maximum with a small gap at the I′-point according to previous study. Before contact, the initial Fermi level of Ag is located above the intrinsic Sb₂Te₃. After Ag decoration, the presence of Ag nanoparticles pins the effective Fermi level of the present nanocomposites around the work function of silver due to the large carrier density in the metallic layer. As can be seen, the blend band gap between the host Sb₂Te₃ semiconductor and metallic Ag nanoparticles forms a Schottky barrier, which is believed to be much better than Ohmic contact. Moreover, the potential barrier height (˜150 meV) is around the theoretical optimized height of 100 me V. Therefore, interfaces in Ag—Sb₂Te₃ nanoplates induce energy-dependent carrier scattering by introducing a Schottky barrier to filter carriers with low energy, i.e. the carrier filtering technique described above is preventing the transport of the lower-energy carriers, which results in an increase in the moment of the differential conductivity about the Fermi level. In summary, increasing the electrical conductivity while maintaining or even enhancing the Seebeck coefficient by chopping the distribution cold carriers is achieved with the introduced self-assembled heterojunction architectures, leading to a dramatically increased power factor for the present flexible thermoelectric fabrics. Further, to roughly estimate the thermal conductivity of the present system, we made samples with thickness around 100 μm. The room temperature thermal conductivity of Ag-decorated Sb₂Te₃ nanocomposites was determined around 0.44 W/m·K, which gives a ZT of 0.23.

### Example 2—Composite Nanoparticle Assembly

Fabrication of n-Type Bi₂Te₃ Nanoplates

In order to fabricate Bi₂Te₃ nanoplates, 2 mmol Bi(N0₃)₃ and 3 mmol Na₂Te0₃ was dissolved in 70 mL ethylene glycol, 1.5 g NaOH was added with vigorous stirring, and followed by 0.5 g polyvinylpyrrolidone (PVP, Ms=40000 g/mol) and refluxing the mixture at 185° C. over night. After the mixture cooled to room temperature, acetone was used to precipitate the fabricated Bi₂Te₃ nanoplates and was washed in Ethanol. This process was repeated three times to remove any unreacted chemicals and ethylene glycol from the surface.

Fabrication of p-type Sb₂Te₃ nanoplates

In a typical synthesis, 70 ml ethylene glycol (EG) solution containing mixed antimony trichloride (SbCl₃, 6 mmol), tellurium dioxide (Te0₂, 9 mmol), sodium hydroxide (NaOH, 1.5 g), and polyvinylpyrrolidone (PVP, Ms=40000 g/mol, 0.8 g) are heated to 120° C. 10 ml hydrazine hydrate (N₂H₄) was injected (with injection rate 2.5 ml/min), and the solution was maintained at 130° C. for 3 hours. After which, the mixture is heated at 155° C. under reflux for another 15 hours. The precipitate is collected by centrifugation, and washed with ethanol at least three times to remove any unreacted chemicals and ethylene glycol from the surface.

Fabrication of Self-Assembling Ag Decorated Bi₂Te₃ and Sb₂Te₃ Nanoplates

For the fabrication of Ag-decorated Bi₂Te₃/Sb₂Te₃, 1 mmol as-fabricated Bi₂Te₃/Sb₂Te₃ was dispersed in 70 mL EG, and a proper amount of AgNO₃ was added with gently and stirred over night at room temperature. The precipitate was collected by centrifugation and washed with ethanol at least three times. The fabrication of Cu-decorated Bi₂Te₃/Sb₂Te₃ is similar to that of Ag, except CuI/CuCl was used with a reaction temperature around 60° C. This synthesis protocol enabled a high batch-to-batch reproducibility and a high material yield larger than 90%.

### Bulk Nanomaterial Consolidation

The dried nanocomposites were loaded into a graphite die and compacted into pellets (Ø10 mm 30×˜1.5 mm). The process was carried out in Ar atmosphere, using a custom-made hot press to simultaneously apply a pressure of 70 MPa and a temperature of 370-380° C. for 30 min. In this system, the heat was provided by an induction coil operated at 30-80 KHz and it was applied directly to a graphite die acting as a susceptor. Fast heating ramps of 20° C.^{s-1} are reached by this method with a 25 kW induction heater. All the pellets were mechanically robust enough to endure polishing.

### Characterization

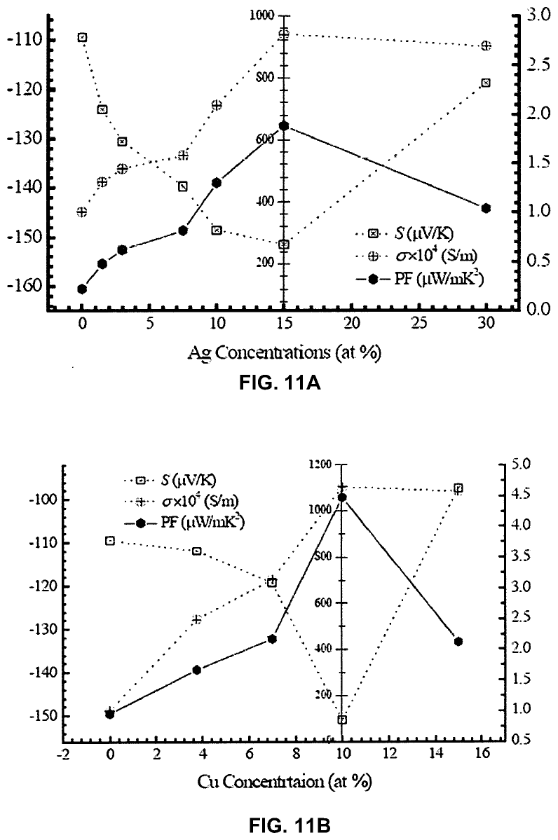

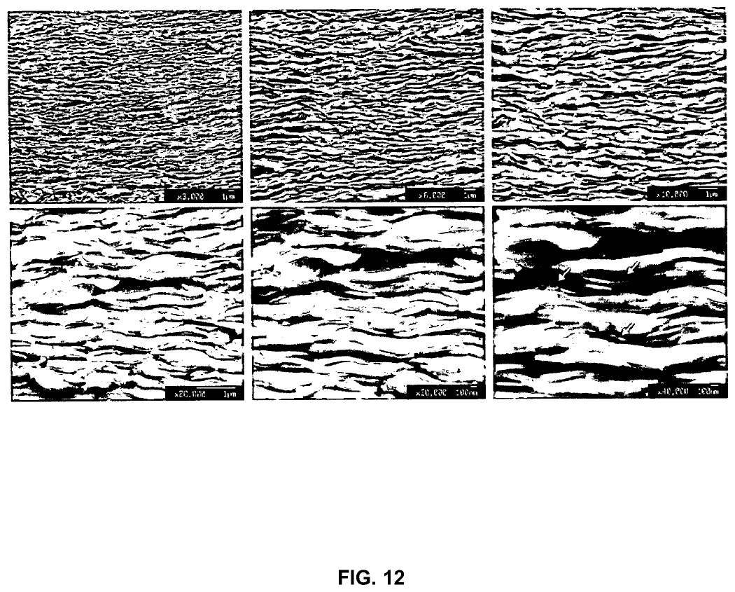

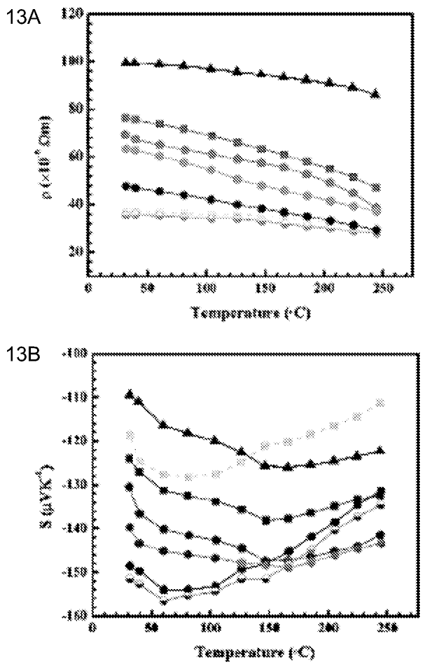

FIG. 9A illustrates temperature dependent electrical properties of Ag-decorated Bi₂Te₃ pellets with different Ag concentrations. FIG. 9B illustrates temperature dependent thermal transport properties of Ag-decorated Bi₂Te₃ pellets with different Ag concentrations. FIG. 10 illustrates temperature dependent electrical and thermal transport properties of Cu-decorated Bi₂Te₃ pellets with different Cu concentrations. Typically, metal-free Bi₂Te₃ exhibits a relatively low electrical conductivity (σ) around 1.0×10⁴ S/m at room temperature (RT). One reason for this low value compared with Bi₂Te₃ ingot is the thermal degradation residue from the capping PVP ligand. The σ gradually increases with the self-assembled metallic nanoparticles. For example, nanocomposites with 15 at % Ag exhibit a significantly increased a up to 2.8×10⁴ S/m at RT, which is nearly three times compared with pure Bi₂Te₃. With temperature, all the nanocomposites show a nondegenerate semiconductor behavior, i.e. the a increases slightly with the temperature over the studied measurement range 300-550 K. This is in agreement with the nanostructured Bi₂Te₃ observed previously. This behavior can be attributed to the thermal excitation carrier concentrations (n) across the band gap and the increased extrinsic n with the increasing temperature.

A simultaneous 35% increase in S (negative) is seen with the decorated nanoparticles, which enhances from 110 to 150 μV/K at RT for Ag-free Bi₂Te₃ and Ag-decorated Bi₂Te₃, respectively. This causes the power factor (PF=σS²) keeping increasing until the amount of Ag reaches 15%, with a champion value of 650 μW/mK² at RT. Further increase of Ag failed to enhance the a. With the decoupled σ and S, the overall PF exhibits a five times increase for the nanocomposites over the original Bi₂Te₃.

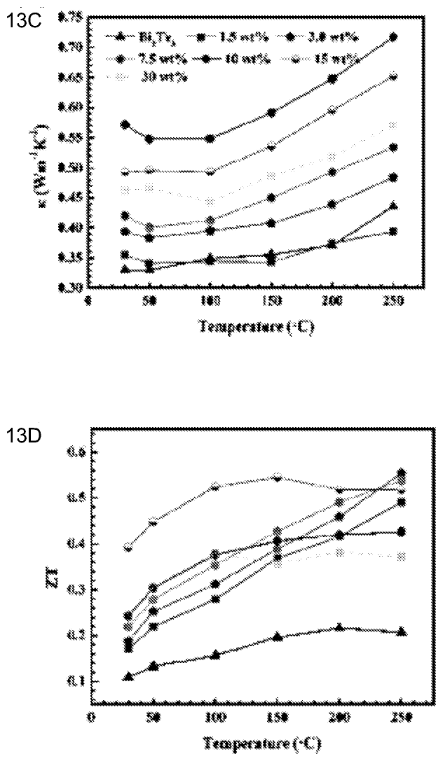

For Cu-decorated Bi₂Te₃ system, this decoupled phenomenon is similar but become much more strengthened, i.e. the absolute value of S shows a 35% increase from 110 to 150 μV/K as the content of Cu increases. The σ enhanced dramatically from 1×10⁴ to 4.6×10⁴ S/m (with Cu concentration around 10 at %). The highest PF of Cu-decorated Bi₂Te₃ reaches 1060 μW/mK² at RT, which is nearly nine times higher than the original Bi₂Te₃. The maximum PF of 1530 μW/mK² at 160° C. was achieved for the Cu-decorated Bi₂Te₃ containing 10 at % Cu. The RT electrical performance for both Cu- and Ag-decorated Bi₂Te₃ are summarized in FIGS. 11A and 11B, demonstrating obviously decoupled σ and S i.e. the S and σ increase in parallel with the introduced self-assembled heterojunction architectures. Compared with the Ag-free Bi₂Te₃ matrix, a gradual increase in carrier concentrations (n) in the Ag-decorated Bi₂Te₃ nanocomposites is observed. Nanocomposites with self-assembled metal nanoparticles increases the n, partially compensating the reduced μ. In general, S tends to decrease with the increased n. For the present self-assembled heterojunction system, the parallel enhancement of σ and S might arise from the simultaneous occurrence of parabolic bands across the Fermi surface and flat bands near the Fermi surface of Bi₂Te₃. Meanwhile, the interactions among the electron-electron, electron-phonon, and the porous three-dimensional structure that is distinct from the tightly stacked bulk materials can also contribute to the increased S.

It is seen that K_{L} shows a continuous decrease with Ag concentrations. A similar trend is observed in Cu-decorated Bi₂Te₃ systems, with a relatively low K_{L} for the champion sample. In other words, a considerable reduction K_{L} was achieved with the introduced self-assembled metal nanoparticles arising from the lattice mismatch/bending and the difference of lattice vibrations between the host semiconductor and the decorated nanoparticles around the grain boundaries. Taking advantages of the enhanced PF and the suppressed K, the resulted thermoelectrical ZT is increased from 0.1 to 0.3 via the present heterojunction architectures for Ag-decorated Bi₂Te₃. For the Cu-decorated Bi₂Te₃ system, the ZT is optimized to 0.3 at RT.

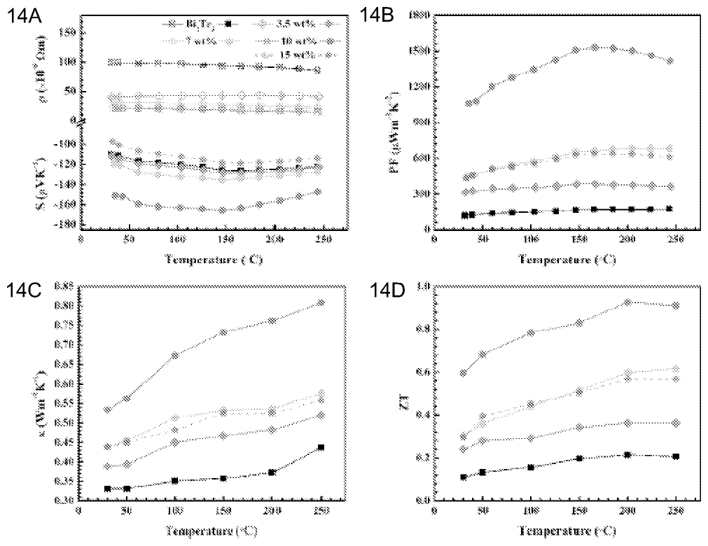

Turning to FIGS. 13A-13D, it can be seen in FIG. 13A that temperature dependent electrical resistivity p decreases for Ag-decorated Bi₂Te₃ nanoplates as Ag concentration increases from 0% to 15% but electrical resistivity p does not further decrease as the percentage of Ag increases from 15% to 30%. Turning to FIG. 13B, the Seebeck coefficient generally decreases (becomes more negative) as percent Ag increases until a value of around 7.5% and, above which the Seebeck coefficient shows an increase with temperature. Between 15% and 30% Ag, there is a large increase in the PF. With respect to thermal conductivity κ in FIG. 13C, the value generally increases through 10% Ag and then decreases again between 10% and 15% and then to 30%. FIG. 13D indicates that the figure of merit ZT for Ag-decorated Bi₂Te₃ nanoplates generally increases until somewhere between 15% and 30% by weight Ag.

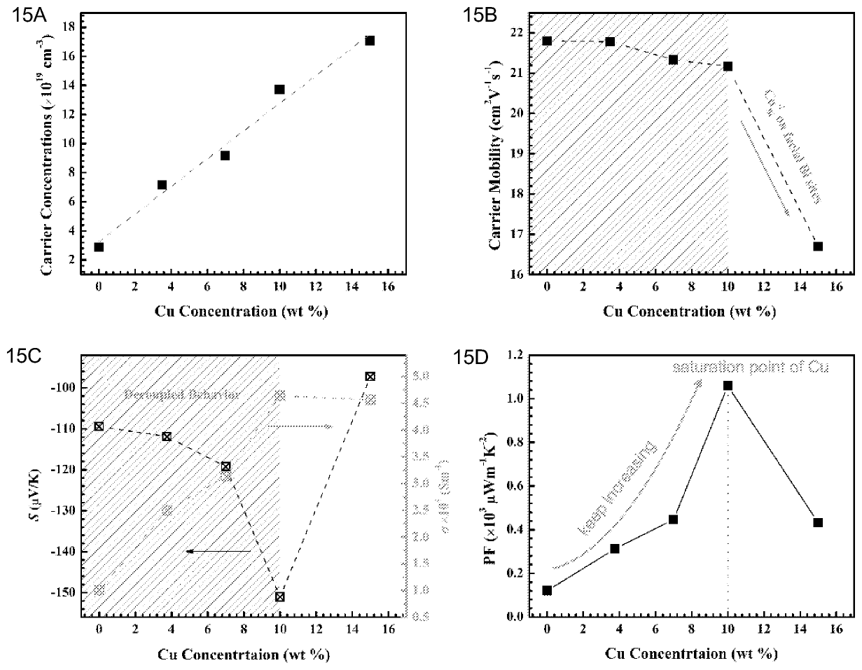

Turning to FIGS. 14A-14D, it can be seen in FIG. 14A that temperature dependent electrical resistivity p decreases for Cu-decorated Bi₂Te₃ nanoplates as Cu concentration increases from 0% to 10% but electrical resistivity does not further decrease as the percentage of Cu increases from 10% to 15%. The same figure also shows that the Seebeck coefficient becomes more negative as Cu % is increased to 10% but the trend reverses between 10% and 15%. Turning to FIG. 14B, the power factor PF generally decreases as percent Cu increases until a value of around 7.5% and, above which the PF shows an increase with temperature. Between 15% and 30% Cu, there is a large increase in the PF. With respect to thermal conductivity κ in FIG. 14C, the value generally increases through 10% Cu and then decreases again between 10% and 15%. FIG. 14D indicates that the figure of merit ZT for Cu-decorated Bi₂Te₃ nanoplates generally increases through 10% and decreases between 105 and 15%.

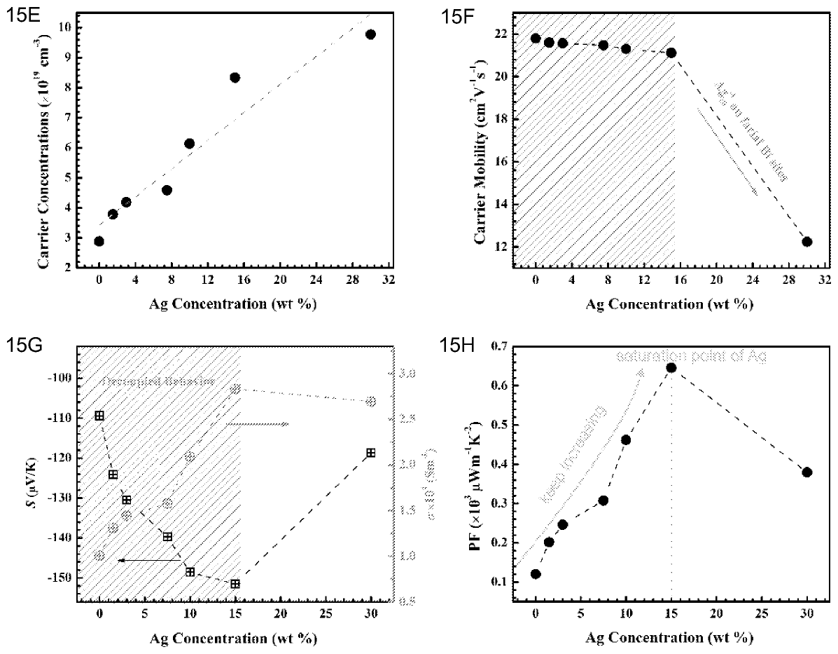

FIGS. 15A-15D indicate that carrier concentration increases with weight percent Cu concentration (FIG. 15A) but that carrier mobility drops precipitously above 10 weight % Cu (FIG. 15B). Electrical conductivity and PF reach maxima at around 10% Cu (FIGS. 15C and 15D) while Seebeck coefficient is most negative at this value. FIGS. 15E-15H indicate that carrier concentration increases with weight percent Ag concentration (FIG. 15E) but that carrier mobility drops precipitously above 15 weight % Ag (FIG. 15F). Electrical conductivity and PF reach maxima at around 15% Ag (FIGS. 15G and 15H) while Seebeck coefficient is most negative at this value. The graphs show that a significant shift in behavior is associated with a specific dopant level, suggesting that the metal dopant may saturate a useful binding location and begin to bind to the nanoplate at sites that interfere with desirable effects as the concentration of dopant is increased.

It appears that, as the weight percent of metal nanoparticles increases, increased occupancy at the edges of the planar nanoplatelets improves thermoelectric properties with an optimum of 8-10 weight percent Cu for Cu-decorated Bi₂Te₃ nanoplates and 10-15 weight percent Ag for Ag-decorated Bi₂Te₃ nanoplates.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the invention.

1. A composite nanoparticle assembly comprising:
semiconductor nanoparticles comprising opposing front and back faces and opposing sidewalls extending between the front and back faces,
wherein opposing sidewalls of the semiconductor nanoparticles are separated by a distance of at least 500 nm and
wherein spacing between the semiconductor nanoparticles is bridged by metallic nanoparticles bonded to the sidewalls of the semiconductor nanoparticles.

2. A composite nanoparticle composition comprising:
a semiconductor nanoparticle including a front face and an opposing back face and sidewalls extending between the front and back faces; and
metallic nanoparticles bonded to at least one of the sidewalls establishing a metal-semiconductor junction;
wherein opposing sidewalls of the nanoparticle are separated by a distance of more than 500 nm and said front face and opposing back face are separated by a distance of at least 20 nm.

3. The composite nanoparticle composition of claim 2, wherein the metallic nanoparticles are bonded to a plurality of the sidewalls establishing multiple metal-semiconductor junctions.

4. The composite nanoparticle composition of claim 2, wherein the metallic nanoparticles have a diameter of around 40 nm.

5. The composite nanoparticle of claim 2, wherein a Schottky barrier is established at the metal-semiconductor junction and said Schottky barrier has a height of at least 100 meV.

6. The composite nanoparticle of claim 2, wherein the semiconductor nanoparticles is a chalcogenide.

7. The composite nanoparticle of claim 2, wherein the metallic nanoparticles are formed of one or more transition metals.

8. The composite nanoparticles of claim 7, wherein said one or more transition metals are selected from Groups IVA-VIIIA and Group IB of the Periodic Table and a noble metal.

9. The composite nanoparticle of claim 2, wherein the semiconductor nanoparticle is a platelet.

10. The composite nanoparticle of claim 2, further comprising an interfacial transition region between the semiconductor nanoparticle and metallic nanoparticles and wherein the interfacial transition region comprises metal atoms chemical bonded to atoms of the semiconductor nanoparticle.

11. The composite nanoparticle of claim 10, wherein the interfacial transition region comprises Sb₂Te₃—Ag₂Te—Ag.

12. The composite nanoparticle assembly of claim 1, wherein the bridging metallic nanoparticles establish metal-semiconductor junctions with the sidewalls of the semiconductor nanoparticles.

13. The composite nanoparticle assembly of claim 12, wherein Schottky barriers are established at the metal-semiconductor junctions and wherein said Schottky barriers have a height of at least 100 meV.

14. The composite nanoparticle assembly of claim 1, wherein the semiconductor nanoparticles are chalcogenides.

15. The composite nanoparticles assembly of claim 1, wherein metallic nanoparticles are formed of one or more transition metals.

16. The composite nanoparticle assembly of claim 15, wherein the one or more transition metals are selected from Groups IVA-VIIIA and Group IB of the Periodic Table and a noble metal.

17. The composite assembly of claim 1, wherein the semiconductor nanoparticles are platelets.

18. The composite assembly of claim 1, wherein the metallic nanoparticles have a diameter of around 40 nm.
